(19) United States
(12) Patent Application Publication
(10) Pub. No.: US 2026/0082955 A1
(43) Pub. Date: Mar. 19, 2026

(54) SEMICONDUCTOR DEVICE AND METHOD FOR MANUFACTURING THE SAME

(71) Applicant: Kioxia Corporation, Tokyo (JP)

(72) Inventor: Takahiro OGURI, Kawasaki Kanagawa (JP)

(21) Appl. No.: 19/078,109

(22) Filed: Mar. 12, 2025

(30) Foreign Application Priority Data
Sep. 17, 2024 (JP) 2024-160275

(51) Int. Cl. H01L 23/538; H01L 21/48; H01L 25/00; H01L 25/07

(52) U.S. Cl. CPC H10W 70/65; H10W 70/05; H10W 70/611; H10W 90/00; H10W 90/24; H10W 90/754

(57) ABSTRACT

According to one embodiment, a semiconductor device includes a wiring board, a first semiconductor element, a second semiconductor element, a first wire, and a second wire. The wiring board is provided with an electrode including a first portion and a second portion, wherein the electrode includes a step between the second portion and the first portion, and the second portion is higher than the first portion with respect to a base layer of the wiring board. The first semiconductor element is located on the wiring board. The second semiconductor element is located on the first semiconductor element. The first wire has one end connected to a first connection point on the first portion and an opposite end connected to the first semiconductor element. The second wire has one end connected to a second connection point on the second portion and an opposite end connected to the second semiconductor element.

### CROSS-REFERENCE TO RELATED APPLICATION

This application is based upon and claims the benefit of priority from Japanese Patent Application No. 2024-160275, filed Sep. 17, 2024, the entire contents of which are incorporated herein by reference.

### FIELD

Embodiments described herein relate generally to a semiconductor device and a method for manufacturing the same.

### BACKGROUND

As semiconductor packages are reduced in their sizes, it is often the case that the lengths of finger electrodes connected to semiconductor chips via wires are shortened. However, shortening the lengths of finger electrodes makes it difficult to ensure clearance among a plurality of wires, which may cause a risk that the wires are short-circuited.

### BRIEF DESCRIPTION OF THE DRAWINGS

FIG. 1 is a sectional view showing a configuration example of a semiconductor device according to a first embodiment.

FIG. 2 is a plan view showing a finger electrode in the semiconductor device according to the first embodiment.

FIG. 3 is a sectional view showing a method for manufacturing the semiconductor device according to the first embodiment.

FIG. 4 is a sectional view showing the method for manufacturing the semiconductor device according to the first embodiment, which is subsequent to FIG. 3.

FIG. 5 is a sectional view showing the method for manufacturing the semiconductor device according to the first embodiment, which is subsequent to FIG. 4.

FIG. 6 is a sectional view showing the method for manufacturing the semiconductor device according to the first embodiment, which is subsequent to FIG. 5.

FIG. 7 is a sectional view showing the method for manufacturing the semiconductor device according to the first embodiment, which is subsequent to FIG. 6.

FIG. 8 is a plan view showing a semiconductor device according to a first modification of the first embodiment.

FIG. 9 is a sectional view showing an example of the semiconductor device according to the first modification of the first embodiment.

FIG. 10 is a sectional view showing another example of the semiconductor device according to the first modification of the first embodiment.

FIG. 11 is a plan view showing a semiconductor device according to a second modification of the first embodiment.

FIG. 12 is a sectional view showing a semiconductor device according to a third modification of the first embodiment.

FIG. 13 is a sectional view showing a semiconductor device according to a fourth modification of the first embodiment.

FIG. 14 is a sectional view showing a semiconductor device according to a fifth modification of the first embodiment.

FIG. 15 is a sectional view showing a semiconductor device according to a sixth modification of the first embodiment.

FIG. 16 is a sectional view showing a semiconductor device according to a seventh modification of the first embodiment.

FIG. 17 is a plan view showing a finger electrode in the semiconductor device according to the seventh modification of the first embodiment.

FIG. 18 is a sectional view showing a semiconductor device according to a second embodiment.

### DETAILED DESCRIPTION

There is provided a semiconductor device that can ensure clearance among wires, and a method for manufacturing the same.

In general, according to one embodiment, a semiconductor device includes a wiring board, a first semiconductor element, a second semiconductor element, a first wire, and a second wire. The wiring board is provided with an electrode including a first portion and a second portion, wherein the electrode includes a step between the second portion and the first portion, and the second portion is higher than the first portion with respect to a base layer of the wiring board. The first semiconductor element is located on the wiring board. The second semiconductor element is located on the first semiconductor element. The first wire has one end connected to a first connection point on the first portion, and has an opposite end connected to the first semiconductor element. The second wire has one end connected to a second connection point on the second portion, and has an opposite end connected to the second semiconductor element.

Embodiments will be described hereunder with reference to the drawings. In order to facilitate understanding of the description, the same components in the respective drawings are denoted by the same reference signs as much as possible, and duplicate descriptions thereof will be omitted.

### First Embodiment

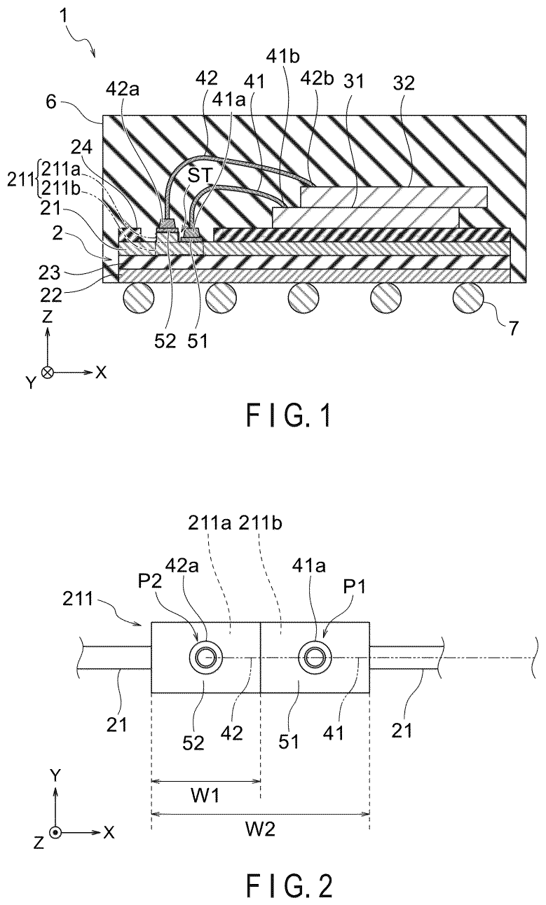

FIG. 1 is a sectional view showing a configuration example of a semiconductor device 1 according to a first embodiment. FIG. 2 is a plan view showing a finger electrode 211 in the semiconductor device 1 according to the first embodiment. In FIG. 1, a Z-direction along a thickness direction of the semiconductor device 1 is defined as an up-direction, and the opposite direction to the Z-direction is defined as a down-direction.

The semiconductor device 1 includes a wiring board 2, a first semiconductor element 31, and a second semiconductor element 32. The semiconductor device 1 further includes a first wire 41, a second wire 42, a first conductive layer 51, a second conductive layer 52, a sealing layer 6, and bump electrodes 7. The semiconductor device 1 may be, for example, a package of a NAND-type flash memory.

The wiring board 2 includes a plurality of wiring layers 21 and 22. The uppermost wiring layer 21 includes a finger electrode 211. In other words, the wiring board 2 is provided with the finger electrode 211. The finger electrode 211 is an example of an electrode. The finger electrode 211 can also be called a bonding finger, a lead electrode, or a lead terminal. The wiring board 2 further includes an interlayer insulating film 23 arranged between the plurality of wiring layers 21 and 22, and a solder resist film 24 provided on the uppermost wiring layer 21. The interlayer insulating film 23 is an example of a base layer. The solder resist film 24 is an example of an insulating film. The solder resist film 24 protects the wiring layer 21, and reduces short-circuit failures. The interlayer insulating film 23 may be made of glass epoxy resin, ceramic or the like. The wiring layers 21 and 22 may each contain, for example, copper. The upper and lower wiring layers 21 and 22 are electrically connected to each other through a via (not shown) penetrating through the interlayer insulating film 23. The bump electrodes 7 are electrically connected to the lower part of the wiring board 2. Note that the wiring board 2 is illustrated in a simplified form in FIG. 1. In other words, other interlayer insulating films and wiring layers may be provided under the wiring layer 22.

The first semiconductor element 31 is placed on the wiring board 2. The first semiconductor element 31 may be bonded onto the solder resist film 24, for example, via an adhesive layer (not shown). The adhesive layer may be paste-like or film-like resin such as nonconductive paste (NCP) or a die attach film (DAF). The first semiconductor element 31 may be, for example, a NAND-type flash memory.

The second semiconductor element 32 is placed on the first semiconductor element 31. The second semiconductor element 32 may be bonded onto the first semiconductor element 31, for example, via an adhesive layer (not shown) such as NCP or a DAF. Like the first semiconductor element 31, the second semiconductor element 32 may be, for example, a NAND-type flash memory. A controller chip for controlling the first semiconductor element 31 may be used as the second semiconductor element 32 instead of the NAND-type flash memory.

As described above, the finger electrode 211 is provided on the wiring board 2. More specifically, the finger electrode 211 forms a part of the uppermost wiring layer 21. In the example shown in FIG. 1 and FIG. 2, the finger electrode 211 extends along an X-direction. The finger electrode 211 is electrically connected to both the first semiconductor element 31 and the second semiconductor element 32 via the wires 41 and 42. One finger electrode 211 has a first connection point P1 and a second connection point P2 as two connection points for connecting the finger electrode 211 to the first semiconductor element 31 and the second semiconductor element 32 via the wires 41 and 42. In other words, one finger electrode 211 is multi-bonded to the two semiconductor elements 31 and 32 via the two wires 41 and 42 at the two connection points P1 and P2, respectively.

As shown in FIG. 1 and FIG. 2, the finger electrode 211 has an upper layer portion 211a and a lower layer portion 211b. The lower layer portion 211b is thinner in the Z-direction than the upper layer portion 211a. In other words, the upper surface of the lower layer portion 211b is spaced apart from the upper surface of the interlayer insulating film 23 in the Z-direction by a smaller distance than it is spaced apart from the upper surface of the upper layer portion 211a. There is a step ST between the upper layer portion 211a and the lower layer portion 211b. The upper layer portion 211a is located at a greater height than the lower layer portion 211b in the Z-direction. In other words, the upper surface of the upper layer portion 211a is spaced apart from the upper surface of the interlayer insulating film 23 in the Z-direction by a larger distance than it is spaced apart from the upper surface of the lower layer portion 211b. In other words, the upper surface of the upper layer portion 211a is located above the upper surface of the lower layer portion 211b. The upper layer portion 211a is partially provided on the lower layer portion 211b so as to create the step ST between the upper layer portion 211a and the lower layer portion 211b.

The first connection point P1 is located on the lower layer portion 211b. More specifically, in the example shown in FIG. 1 and FIG. 2, the first conductive layer 51 is provided on the lower layer portion 211b in a region where the upper layer portion 211a is not provided. The first conductive layer 51 may be formed of the same material as the first wire 41. The first conductive layer 51 may contain gold. The first connection point P1 is located on the first conductive layer 51.

The second connection point P2 is located on the upper layer portion 211a. More specifically, in the example shown in FIG. 1 and FIG. 2, the second conductive layer 52 is provided on the upper layer portion 211a. Like the first conductive layer 51, the second conductive layer 52 may contain gold. The second connection point P2 is located on the second conductive layer 52.

The upper layer portion 211a is provided directly on the lower layer portion 211b without interposing any other layer (e.g., an insulating layer or the like) between the upper layer portion 211a and the lower layer portion 211b. In other words, the first wire 41 connected to the first connection point P1 on the lower layer portion 211b and the second wire 42 connected to the second connection point P2 on the upper layer portion 211a have the same electric potential. Furthermore, the upper layer portion 211a is not formed as a structure separate from the finger electrode 211 like a bump, but is formed as a part of the finger electrode 211. Therefore, the upper layer portion 211a can be formed simultaneously with the finger electrode 211 using the same material as the finger electrode 211 (i.e., the wiring layer 21).

As described above, one end 41a of the first wire 41 is connected to the first connection point P1 on the lower layer portion 211b. More specifically, the one end 41a of the first wire 41 is connected to the first connection point P1 on the first conductive layer 51. The ratio in the X-direction of the length of one end 41a of the first wire 41 to the length of finger electrode 211 may be different from that shown in FIG. 1. For example, as shown in FIG. 2, the finger electrode 211 may be formed to be sufficiently longer than the one end 41a of the first wire 41 in the X-direction.

An opposite end 41b of the first wire 41 is connected to the first semiconductor element 31. For example, the opposite end 41b of the first wire 41 may be connected to a pad (not shown) provided on the upper surface of the first semiconductor element 31. The pad may be made of, for example, aluminum, gold, copper, or a composite material thereof. In the example shown in FIG. 1, the first wire 41 connects the finger electrode 211 and the first semiconductor element 31 to each other by reverse bonding in which the finger electrode 211 side is subjected to a first bonding and the pad side of the first semiconductor element 31 is subjected to a second bonding. The first bonding may be performed, for example, by ball bonding. The second bonding may be performed, for example, by wedge bonding. In the example shown in FIG. 1, the first wire 41 at the one end 41a side forms a smaller angle with respect to the Z-direction, than the first wire 41 at the opposite end 41b side forms with respect to the Z-direction. The first wire 41 may contain, for example, gold.

As described above, one end 42a of the second wire 42 is connected to the second connection point P2 on the upper layer portion 211a. More specifically, the one end 42a of the second wire 42 is connected to the second connection point P2 on the second conductive layer 52. Since the second connection point P2 is located on the upper layer portion 211a, the second connection point P2 is located at a higher position than the first connection point P1. Therefore, the one end 42a of the second wire 42 is located at a higher position than the one end 41a of the first wire 41.

An opposite end 42b of the second wire 42 is connected to the second semiconductor element 32. For example, the opposite end 42b of the second wire 42 may be connected to a pad (not shown) provided on the upper surface of the second semiconductor element 32. In the example shown in FIG. 1, the second wire 42 connects the finger electrode 211 and the second semiconductor element 32 to each other by reverse bonding in which the finger electrode 211 side is subjected to first bonding and the pad side of the second semiconductor element 32 is subjected to second bonding. In the example shown in FIG. 1, the second wire 42 at the one end 42a side forms a smaller angle with respect to the Z-direction, than the second wire 42 at the opposite end 42b side forms with respect to the Z-direction. The second wire 42 may contain, for example, gold.

The one end 42a of the second wire 42 is connected to the finger electrode 211 at a higher position than the one end 41a of the first wire 41, by the upper layer portion 211a. Therefore, when the one end 42a of the second wire 42 is connected using a capillary, it is possible to prevent the capillary from coming into contact with the first wire 41.

The upper layer portion 211a is provided at a position farther from the first semiconductor element 31 and the second semiconductor element 32 in the −X-direction, than the first connection point P1. In other words, the upper layer portion 211a is provided at a position farther from the first semiconductor element 31 and the second semiconductor element 32 in the −X-direction, than the lower layer portion 211b in a region where the upper layer portion 211a is not provided. In the example shown in FIG. 1 and FIG. 2, the upper layer portion 211a is provided on an end portion side of the finger electrode 211 in the −X-direction.

The position where the first wire 41 connects to the first semiconductor element 31, is closer to the first connection point P1 in the X-direction, than the position where the second wire 42 connects to the second connection element 32, is to the second connection point P2 in the X-direction. The length of the first wire 41 is shorter than the length of the second wire 42.

As shown in FIG. 2, a width W1 of the upper layer portion 211a occupies half a width W2 of the lower layer portion 211b in a direction connecting the first connection point P1 and the second connection point P2 (i.e., the X-direction) in the plan view.

The first wire 41 and the second wire 42 may be, for example, power supply lines. The first wire 41 and the second wire 42 may be ground lines.

Although only one finger electrode 211 is shown in FIG. 1, a plurality of finger electrodes 211 may actually be arranged to be lined up along a Y-direction. In connection with this arrangement, a plurality of first wires 41 and a plurality of second wires 42 which correspond to the finger electrodes 211 may also be arranged to be lined up along the Y-direction.

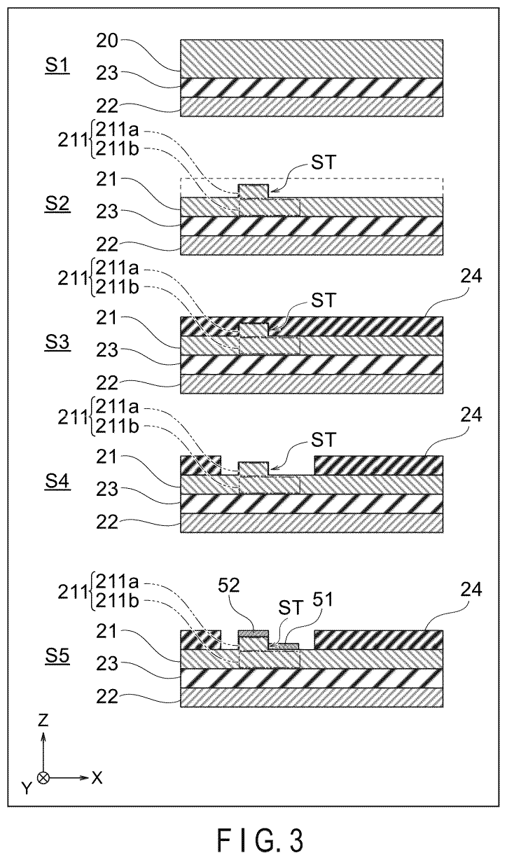

Next, a method for manufacturing the semiconductor device 1 having the above configuration will be described. FIG. 3 is a sectional view showing the method for manufacturing the semiconductor device 1 according to the first embodiment. For example, FIG. 3 will be discussed with respect to manufacturing the semiconductor device 1 to include multiple finger electrodes 211, e.g., lined up in the Y-direction.

First, as shown in FIG. 3, the wiring board 2 includes a conductive layer 20 on which the uppermost wiring layer 21 will be formed (step S1). The conductive layer 20 is formed to be thicker than the uppermost wiring layer 21 will be formed.

Next, the conductive layer 20 is processed by etching to form the finger electrodes 211 together with the uppermost wiring layer 21 (step S2). Each of the finger electrodes 211 is formed to have the upper layer portion 211a and the lower layer portion 211b. In the processing of the conductive layer 20, the shape of the upper layer portion 211a may be formed first, and then the shapes of the lower layer portion 211b and the wiring pattern may be formed.

After forming the finger electrodes 211 together with the uppermost wiring layer 21, a solder resist film 24 is formed on the finger electrodes 211 and the uppermost wiring layer 21 (step S3). In the example shown in FIG. 3, the solder resist film 24 is formed to have such a thickness that it covers the upper ends of the upper layer portions 211a of the finger electrodes 211.

After the solder resist film 24 is formed, the solder resist film 24 is processed by etching so that the finger electrodes 211 are exposed to outside the solder resist film 24 (step S4).

After the solder resist film 24 is processed, the conductive layers 51 and 52 are formed on the finger electrodes 211 by gold plating (step S5). The first conductive layer 51 is formed on the lower layer portion 211b in a region where the upper layer portion 211a is not provided. The second conductive layer 52 is formed on the upper layer portion 211a.

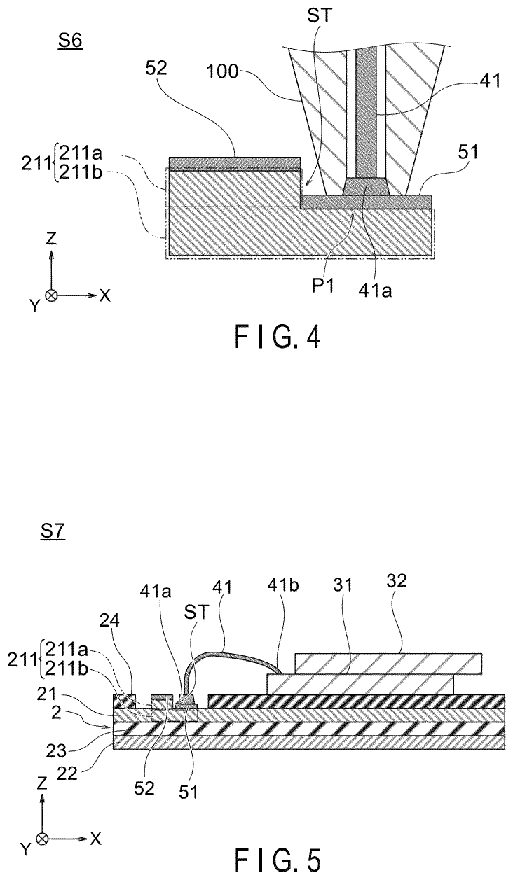

FIG. 4 is a sectional view showing the method for manufacturing the semiconductor device 1 according to the first embodiment, which is subsequent to FIG. 3. For clarity, FIGS. 4-7 will be discussed with respect to a single finger electrode 11. After the conductive layers 51 and 52 are formed, as shown in FIG. 4, first bonding is performed using a capillary 100, for connecting the one end 41a of the first wire 41 to the first connection point P1 on the first conductive layer 51 (step S6). The first bonding of the first wire 41 may be performed, for example, by ball bonding.

FIG. 5 is a sectional view showing the method for manufacturing the semiconductor device 1 according to the first embodiment, which is subsequent to FIG. 4. After the one end 41a of the first wire 41 is connected, the capillary 100 is lifted up from the first connection point P1, and moved so as to obtain the first wire 41 having a desired shape (loop). Next, as shown in FIG. 5, second bonding is performed for connecting the opposite end 41b of the first wire 41 to a pad (not shown) of the first semiconductor element 31 (step S7). The second bonding of the first wire 41 may be performed, for example, by wedge bonding. As a result, the first wire 41 connects the finger electrode 211 and the first semiconductor element 31 to each other by reverse bonding in which the finger electrode 211 side is subjected to first bonding, and the pad side of the first semiconductor element 31 is subjected to second bonding.

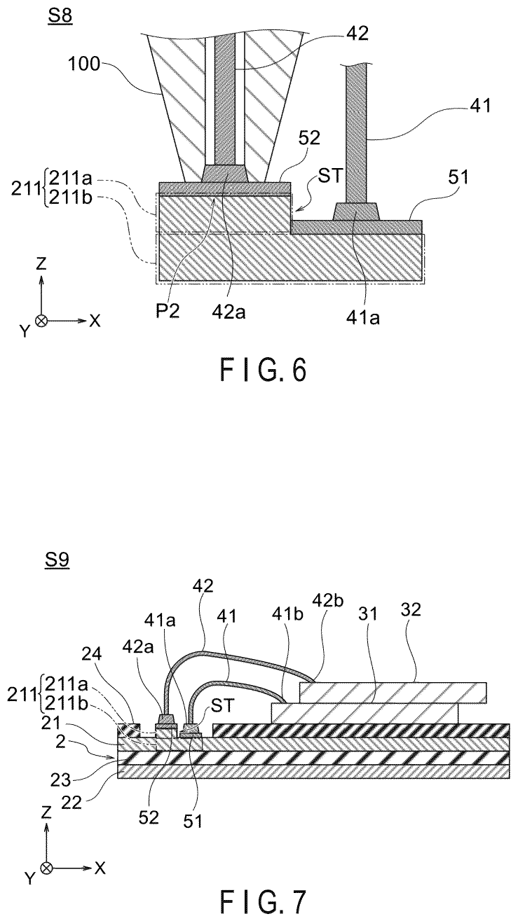

FIG. 6 is a sectional view showing the method for manufacturing the semiconductor device 1 according to the first embodiment, which is subsequent to FIG. 5. After the first wire 41 is connected, as shown in FIG. 6, the first bonding is performed using the capillary 100, for connecting the one end 42a of the second wire 42 to the second connection point P2 on the second conductive layer 52 (step S8). The first bonding of the second wire 42 may be performed, for example, by ball bonding. At this time, the second connection point P2 is located at a higher position than the one end 41a of the first wire 41 due to the added height of the upper layer portion 211a. Therefore, the contact between the capillary 100 and the first wire 41 can be prevented. Since the contact between the capillary 100 and the first wire 41 can be prevented, deformation of the first wire 41 can be prevented. Since the deformation of the first wire 41 can be prevented, the yield of successfully manufacturing the semiconductor device 1 can be improved. Furthermore, for the purpose of elevating the second connection point P2, other methods for manufacturing a semiconductor device may include a process of forming a gold bump on which the second connection point P2 is located. However, according to embodiments, such process of forming a gold bump is not separately required, so the one end 42a of the second wire 42 can be connected more easily and quickly than other methods. Furthermore, by locating the second connection point P2 at a high position, the length of the second wire 42 can be shortened, as compared to if the second connection point P2 were located at the same height as the first connection point P1.

FIG. 7 is a sectional view showing the method for manufacturing the semiconductor device 1 according to the first embodiment, which is subsequent to FIG. 6. After the one end 42a of the second wire 42 is connected, the capillary 100 is lifted up from the second connection point P2, and moved so as to obtain the second wire 42 having a desired shape. Next, as shown in FIG. 7, second bonding is performed for connecting the opposite end 42b of the second wire 42 to a pad (not shown) of the second semiconductor element 32 (step S9). The second bonding of the second wire 42 may be performed, for example, by wedge bonding. As a result, the second wire 42 connects the finger electrode 211 and the second semiconductor element 32 to each other by reverse bonding in which the finger electrode 211 side is subjected to first bonding and the pad side of the second semiconductor element 32 is subjected to second bonding.

As described above, the semiconductor device 1 according to the first embodiment includes the wiring board 2, the first semiconductor element 31, the second semiconductor element 32, the first wires 41, and the second wires 42. The wiring board 2 is provided with the finger electrodes 211 each including the lower layer portion 211b and the upper layer portion 211a. There is the step ST between the lower layer portion 211b and the upper layer portion 211a. The upper layer portion 211a is higher than the lower layer portion 211b in the Z-direction. The first semiconductor element 31 is placed on the wiring board 2. The second semiconductor element 32 is placed on the first semiconductor element 31. The first wire 41 has the one end 41a connected to the first connection point P1 on the lower layer portion 211b, and the opposite end 41b connected to the first semiconductor element 31. The second wire 42 has the one end 42a connected to the second connection point P2 on the upper layer portion 211a, and the opposite end 42b connected to the second semiconductor element 32.

As a result, the one end 42a of the second wire 42 can be connected at a higher position than the one end 41a of the first wire 41, so that a clearance between the first wire 41 and the second wire 42 can be secured. Since the clearance can be secured, a short-circuit between the first wire 41 and the second wire 42 can be prevented. Furthermore, since the length of the second wire 42 can be shortened, the cost required for the second wire 42 can be reduced. In addition, when the first wire 41 and the second wire 42 connect the finger electrode 211 to the semiconductor elements 31 and 32 by reverse bonding, it is possible to prevent the capillary 100 from coming into contact with the first wire 41. This prevents deformation of the first wire 41 and improves the yield of successfully manufacturing the semiconductor device 1.

Furthermore, according to the first embodiment, the upper layer portion 211a is provided at a position which is farther away from the first semiconductor element 31 and the second semiconductor element 32 in the X-direction, than the first connection point P1.

As a result, the clearance between the first wire 41 and the second wire 42 can be appropriately secured.

Also, according to the first embodiment, the position where the first wire 41 connects to the first semiconductor element 31, is closer to the first connection point P1 in the X-direction, than the position where the second wire 42 connects to the second connection element 32, is to the second connection point P2 in the X-direction.

As a result, the clearance between the first wire 41 and the second wire 42 can be more appropriately secured.

Also, according to the first embodiment, the width of the upper layer portion 211a occupies half the width of the lower layer portion 211b, in the X-direction connecting the first connection point P1 and the second connection point P2 in the plan view.

This allows the finger electrode 211 to have a sufficient width to connect the first wire 41 and the second wire 42, so that the first wire 41 and the second wire 42 can be connected to each other simply and appropriately.

Furthermore, according to the first embodiment, the upper layer portion 211a is formed of the same material as the wirings of the wiring board 2.

This allows the upper layer portion 211a to be formed simultaneously with the wiring layer 21, so that the upper layer portion 211a can be formed efficiently.

Furthermore, according to the first embodiment, after the finger electrodes 211 are formed, the solder resist film 24 is formed on the wiring board 2 before the first semiconductor element 31 is placed on the wiring board 2, and the solder resist film 24 is processed so that the finger electrodes 211 are exposed. Then, the first semiconductor element 31 is placed on the processed solder resist film 24.

As a result, after the finger electrodes 211 are formed, the solder resist film 24 can be formed and processed to expose the finger electrodes 211. As a result, the finger electrodes 211 and the wiring layer 21 can be formed more simply and appropriately as compared with a case where the solder resist film 24 formed on the conductive layer 20 (see FIG. 3) is processed to expose the conductive layer 20, and then the conductive layer 20 is processed to form the finger electrodes 211 and the wiring layer 21.

According to the first embodiment, the finger electrode 211 is connected to the semiconductor elements 31 and 32 by reverse bonding using the first wire 41 and the second wire 42. In other words, the electrical connection between the finger electrode 211 and the wires 41 and 42 includes a first step of connecting the one end 41a of the first wire 41 to the first connection point P1 on the lower layer portion 211b, and a second step after the first step, of connecting the opposite end 41b of the first wire 41 to the first semiconductor element 31. The electrical connection between the finger electrode 211 and the wires 41 and 42 further includes a third step of connecting the one end 42a of the second wire 42 to the second connection point P2 on the upper layer portion 211a, and a fourth step after the third step, of connecting the opposite end 42b of the second wire 42 to the second semiconductor element 32.

This ensures a clearance between the first wire 41 and the second wire 42, and also prevents contact between the capillary 100 and the first wire 41.

The following modifications can be applied to the first embodiment.

### First Modification

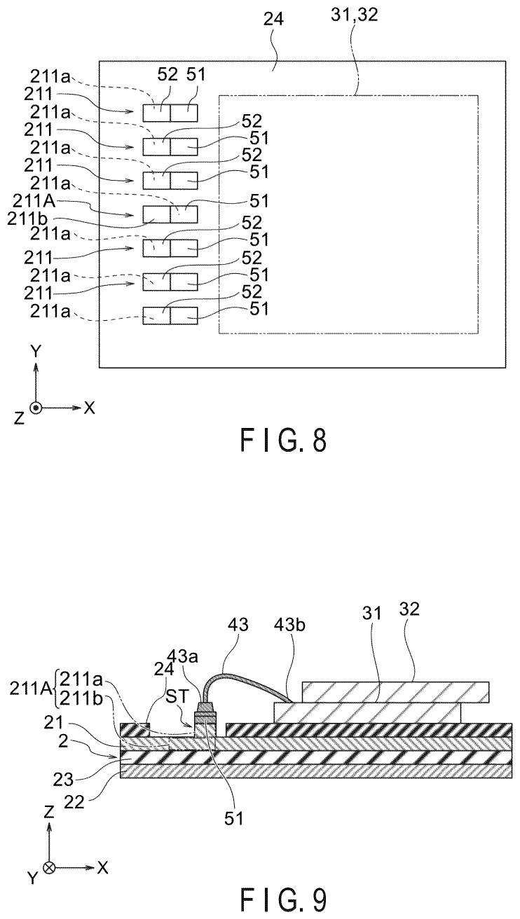

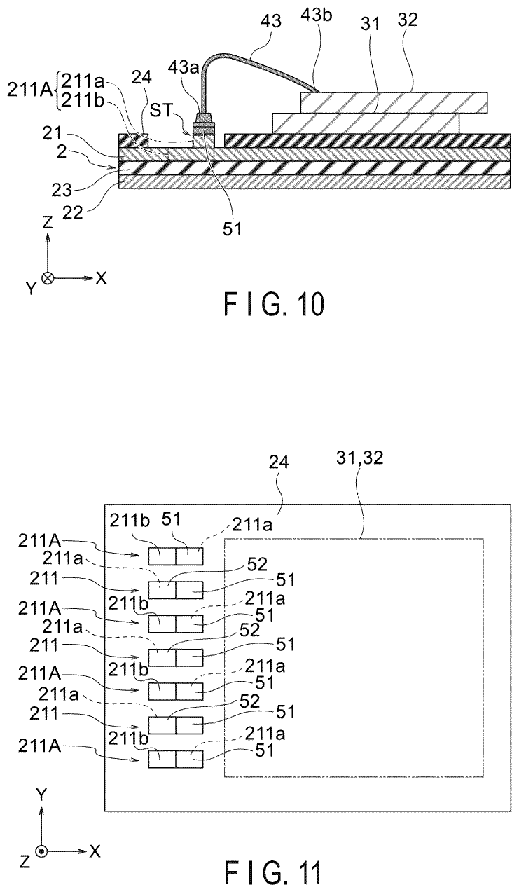

Next, a first modification of the first embodiment, which includes finger electrodes 211 having upper layer portions 211a provided at positions close to semiconductor elements 31 and 32, will be described while focusing on the differences from the first embodiment. FIG. 8 is a plan view showing the semiconductor device 1 according to the first modification of the first embodiment. In FIG. 8, the illustrations of the first wire 41 and the second wire 42 are omitted. Furthermore, in FIG. 8, the illustrations of the first semiconductor element 31 and the second semiconductor element 32 are simplified. FIG. 9 is a sectional view showing an example of the semiconductor device 1 according to the first modification of the first embodiment. FIG. 10 is a sectional view showing the semiconductor device according to another example of the first modification of the first embodiment.

Up to this point, the example has been described of the finger electrode 211 whose upper layer portion 211a is provided on a far side of the lower portion 211b with respect to the semiconductor elements 31 and 32 (that is, at a position furthest away from the semiconductor elements 31 and 32). In contrast to the above example, in an example shown in FIG. 8 and FIG. 9, the semiconductor device 1 is provided with a second finger electrode 211A whose upper layer portion 211a is provided on a near side of the lower layer portion 211b with respect the semiconductor elements 31 and 32. The semiconductor device 1 is further provided with a plurality of other finger electrodes 211 whose upper layer portions 211a are provided on the far side of the lower portion 211b with respect to the semiconductor elements 31 and 32. In other words, the second finger electrode 211A has the upper layer portion 211a which is provided on the lower layer portion 211b to be located at a position close to the semiconductor elements 31 and 32.

In the example shown in FIG. 8, the second finger electrode 211A is provided in the center of the plurality of finger electrodes 211 in the Y-direction. The configuration of the finger electrodes 211 other than the second finger electrode 211A, is similar to the configuration thereof in the first embodiment.

Unlike the upper layer portion 211a of the finger electrode 211, which has a main purpose to ensure a clearance between the wires 41 and 42 used in the multi-bonding to the finger electrode 211, the upper layer portion 211a of the second finger electrode 211A does not have the purpose of ensuring a clearance. Instead, the main purpose of the upper layer portion 211a of the second finger electrode 211A is to shorten the length of a single wire to be connected to the second finger electrode 211A.

A first conductive layer 51 is provided on the upper layer portion 211a of the second finger electrode 211A. One end 43a of a third wire 43 is connected to a third connection point on the first conductive layer 51. The configuration of the third connection point is similar to that of the first connection point P1 on the first conductive layer 51 shown in FIG. 2 except that it is located on the upper layer portion 211a. Therefore, for illustration of the third connection point on the first conductive layer 51, the first connection point P1 on the first conductive layer 51 shown in FIG. 2 may be referred to. In the example shown in FIG. 9, an opposite end 43b of the third wire 43 is connected to a pad (not shown) of the first semiconductor element 31. In the example shown in FIG. 9, the third wire 43 connects the second finger electrode 211A and the first semiconductor element 31 to each other by reverse bonding in which the second finger electrode 211A side is subjected to first bonding and the pad side of the first semiconductor element 31 is subjected to second bonding.

No wire is connected onto the lower layer portion 211b on the opposite side of the upper layer portion 211a. In the example shown in FIG. 8, the first wires 41 and the second wires 42 connected to the finger electrodes 211 other than the second finger electrode 211A may be, for example, power supply lines or ground lines. On the other hand, the third wire 43 connected to the second finger electrode 211A may be, for example, a signal line.

As shown in FIG. 10, the opposite end 43b of the third wire 43 may be connected to the second semiconductor element 32 instead of the first semiconductor element 31. In the example shown in FIG. 10, the third wire 43 connects the second finger electrode 211A and the second semiconductor element 32 to each other by reverse bonding in which the second finger electrode 211A side is subjected to first bonding and the pad side of the second semiconductor element 32 is subjected to the second bonding.

According to the example shown in FIG. 8 to FIG. 10, the wiring board 2 is further provided with the second finger electrode 211A having the lower layer portion 211b and the upper layer portion 211a with the step ST between the upper layer portion 211a and the lower layer portion 211b. The upper layer portion 211a is higher than the lower layer portion 211b in the Z-direction. Furthermore, the semiconductor device 1 further includes the third wire 43 having the one end 43a connected onto the upper layer portion 211a of the second finger electrode 211A and the opposite end 43b connected to the first semiconductor element 31 or the second semiconductor element 32. The upper layer portion 211a of the second finger electrode 211A is provided at a position of the second finger electrode 211A, that is closest to the first semiconductor element 31 and the second semiconductor element 32.

According to the example shown in FIG. 8 to FIG. 10, the second finger electrode 211A having the upper layer portion 211a provided on the side closest to the semiconductor elements 31 and 32 is provided, whereby it is possible to shorten the length of the third wire 43 to be connected between the upper layer portion 211a of the second finger electrode 211A and the first semiconductor element 31 or the second semiconductor element 32.

### Second Modification

FIG. 11 is a plan view showing the semiconductor device 1 according to a second modification of the first embodiment. With reference to FIGS. 8 to 10, the example has been described of the semiconductor device 1 having only one second finger electrode 211A. In contrast, as shown in FIG. 11, a plurality of second finger electrodes 211A may be provided. In an example shown in FIG. 11, the finger electrodes 211 having the upper layer portions 211a provided on the far side with respect to the semiconductor elements 31 and 32, and the second finger electrodes 211A having the upper layer portions 211a provided on the near side with respect to the semiconductor elements 31 and 32, are alternately and repeatedly arranged along the Y-direction. According to the example shown in FIG. 11, the degree of freedom in arrangement of the finger electrodes 211 and 211A can be improved.

### Third Modification

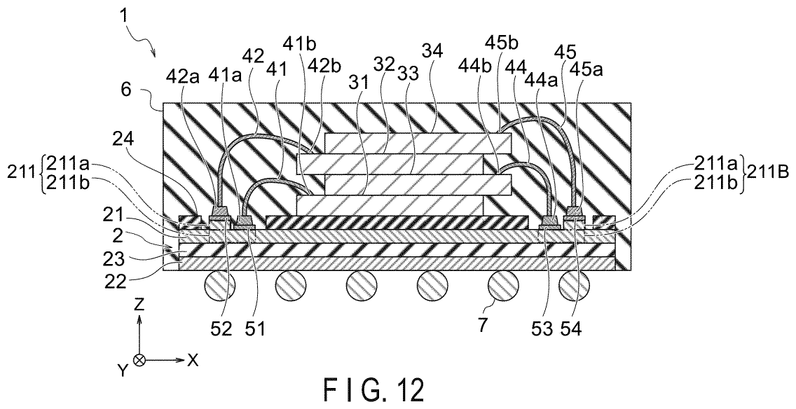

Next, a third modification of the first embodiment, which further includes a third semiconductor element 33 and a fourth semiconductor element 34, will be described while focusing on the differences from the first embodiment. FIG. 12 is a sectional view showing the semiconductor device 1 according to the third modification of the first embodiment.

Up to this point, the example has been described of the semiconductor device 1 in which the first semiconductor element 31 and the second semiconductor element 32 are mounted on the wiring board 2. In addition, in an example shown in FIG. 12, the semiconductor device 1 further includes a third semiconductor element 33 and a fourth semiconductor element 34. The third semiconductor element 33 and the fourth semiconductor element 34 may be, for example, NAND-type flash memories. The third semiconductor element 33 and the fourth semiconductor element 34 may be controller chips.

The third semiconductor element 33 is provided between the first semiconductor element 31 and the second semiconductor element 32. The third semiconductor element 33 is bonded between the first semiconductor element 31 and the second semiconductor element 32 via an adhesive layer (not shown), such as NCP or a DAF. The fourth semiconductor element 34 is bonded onto the second semiconductor element 32 via an adhesive layer (not shown) such as NCP or a DAF.

In the example shown in FIG. 12, the wiring board 2 includes a third finger electrode 211B provided on the electrode layer 21. The third finger electrode 211B is provided on the opposite side of the semiconductor elements 31 to 34 as the finger electrode 211, the semiconductor elements 31 to 34 being sandwiched between the finger electrode 211 and the third finger electrode 211B. The third finger electrode 211B is provided in the +X-direction with respect to the semiconductor elements 31 to 34. The third finger electrode 211B includes a lower layer portion 211b and an upper layer portion 211a with a step between the upper layer portion 211a and the lower layer portion 211b. The upper layer portion 211a is higher than the lower layer portion 211b in the Z-direction. The upper layer portion 211a is provided on the lower layer portion 211b on a far side with respect to the semiconductor elements 31 to 34.

One end 44a of a fourth wire 44 is connected to a fourth connection point on the lower layer portion 211b in a region where the upper layer portion 211a is not provided. In the example shown in FIG. 12, a third conductive layer 53 is provided on the lower layer portion 211b. The third conductive layer 53 may contain, for example, gold. The fourth connection point is placed on the third conductive layer 53. Note that the configuration of the fourth connection point on the third conductive layer 53 is similar to a configuration in which the first connection point P1 on the first conductive layer 51 shown in FIG. 2, is inverted from right to left. Therefore, for illustration of the fourth connection point, the first connection point P1 shown in FIG. 2 may be referred to. An opposite end 44b of the fourth wire 44 is connected to a pad (not shown) provided on the upper surface of the third semiconductor element 33. In the example shown in FIG. 12, the fourth wire 44 is connected by reverse bonding in which the third finger electrode 211B side is subjected to first bonding and the pad side of the third semiconductor element 33 is subjected to second bonding.

One end 45a of a fifth wire 45 is connected to a fifth connection point on the upper layer portion 211a of the third finger electrode 211B. In the example shown in FIG. 12, a fourth conductive layer 54 is provided on the upper layer portion 211a of the third finger electrode 211B. The fourth conductive layer 54 may contain, for example, gold. The fifth connection point is located on the fourth conductive layer 54. Note that the configuration of the fifth connection point on the fourth conductive layer 54 is similar to a configuration in which the second connection point P2 on the second conductive layer 52 shown in FIG. 2, is inverted from left to right. Therefore, for illustration of the fifth connection point, the second connection point P2 shown in FIG. 2 may be referred to. An opposite end 45b of the fifth wire 45 is connected to a pad (not shown) provided on the upper surface of the fourth semiconductor element 34. In the example shown in FIG. 12, the fifth wire 45 is connected by reverse bonding in which the third finger electrode 211B side is subjected to first bonding and the pad side of the fourth semiconductor element 34 is subjected to second bonding. The one end 45a of the fifth wire 45 is connected to the third finger electrode 211B by the upper layer portion 211a, at a higher position than the one end 44a of the fourth wire 44 is connected to the third finger electrode 211B by the lower layer portion 211b. Therefore, it is possible to prevent the capillary for connecting the one end 45a of the fifth wire 45 from coming into contact with the fourth wire 44.

According to the example shown in FIG. 12, even when the number of semiconductor elements 31 to 34 to be mounted (i.e., memory capacity) is increased, the clearance between the wires 44 and 45 can be secured by adding a finger electrode 211B provided with an upper layer portion 211a. Furthermore, the contact of the capillary with the fourth wire 44 can be prevented.

### Fourth Modification

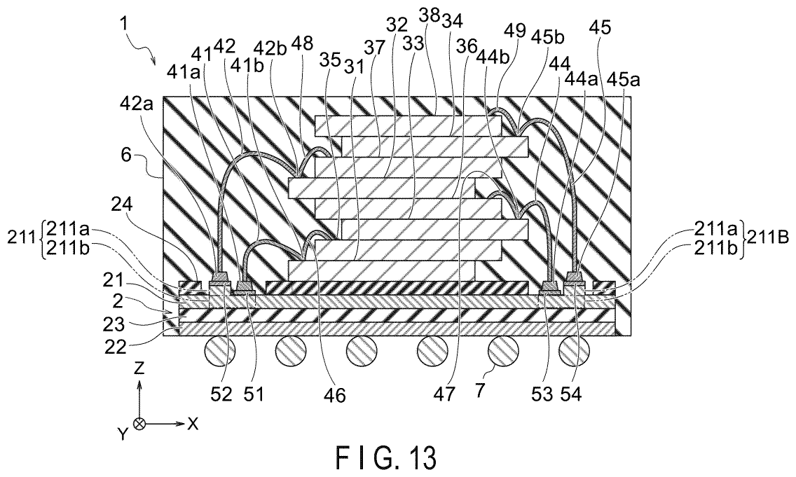

Next, a fourth modification of the first embodiment, in which the number of semiconductor elements to be mounted is further increased, will be described while focusing on the differences from the first embodiment. FIG. 13 is a sectional view showing the semiconductor device 1 according to the fourth modification of the first embodiment.

In an example shown in FIG. 13, a fifth semiconductor element 35 is provided between the first semiconductor element 31 and the third semiconductor element 33. The fifth semiconductor element 35 is bonded between the first semiconductor element 31 and the third semiconductor element 33 via an adhesive layer (not shown) such as NCP or a DAF. A sixth semiconductor element 36 is provided between the third semiconductor element 33 and the second semiconductor element 32. The sixth semiconductor element 36 is bonded between the third semiconductor element 33 and the second semiconductor element 32 via an adhesive layer (not shown) such as NCP or a DAF. A seventh semiconductor element 37 is provided between the second semiconductor element 32 and the fourth semiconductor element 34. The seventh semiconductor element 37 is bonded between the second semiconductor element 32 and the fourth semiconductor element 34 via an adhesive layer (not shown) such as NCP or a DAF. An eighth semiconductor element 38 is placed on the fourth semiconductor element 34. The eighth semiconductor element 38 is bonded onto the fourth semiconductor element 34 via an adhesive layer (not shown) such as NCP or a DAF.

In the example shown in FIG. 13, the first semiconductor element 31 and the fifth semiconductor element 35 are electrically connected to each other via a sixth wire 46. The fifth semiconductor element 35 may be electrically connected to the finger electrode 211 via the first wire 41 and the sixth wire 46. The third semiconductor element 33 and the sixth semiconductor element 36 are electrically connected to each other via a seventh wire 47. The sixth semiconductor element 36 may be electrically connected to the third finger electrode 211B via the fourth wire 44 and the seventh wire 47. The second semiconductor element 32 and the seventh semiconductor element 37 are electrically connected to each other via an eighth wire 48. The seventh semiconductor element 37 may be electrically connected to the finger electrode 211 via the second wire 42 and the eighth wire 48. The fourth semiconductor element 34 and the eighth semiconductor element 38 are electrically connected to each other via a ninth wire 49. The eighth semiconductor element 38 may be electrically connected to the third finger electrode 211B via the fifth wire 45 and the ninth wire 49.

According to the example shown in FIG. 13, even when the number of semiconductor elements 31 to 38 to be mounted is further increased, the clearance between the wires can be ensured.

### Fifth Modification

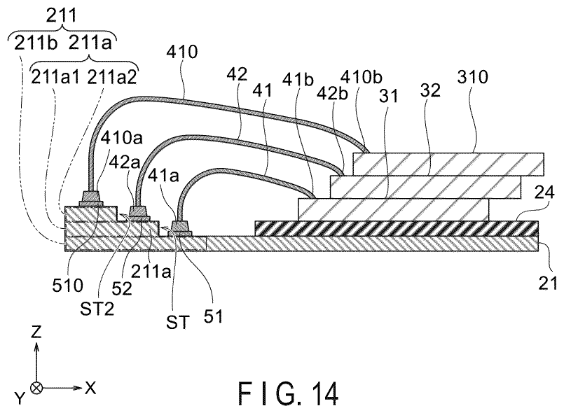

Next, a fifth modification of the first embodiment, in which the number of steps of the finger electrode 211 is increased, will be described while focusing on the differences from the first embodiment. FIG. 14 is a sectional view showing the semiconductor device 1 according to the fifth modification of the first embodiment. Up to this point, the example has been described of the finger electrode 211 provided with the step ST between the upper layer portion 211a and the lower layer portion 211b. In addition, as shown in FIG. 14, the finger electrode 211 may also be provided with a step ST2. The upper layer portion 211a may have a first layer 211a1, and a second layer 211a2, and the step ST2 may be between the second layer 211a2 and the first layer 211a1. The second layer 211a2 is higher than the first layer 211a1 in the Z-direction. Indeed, the finger electrode 211 may be provided with two or more steps.

In the example shown in FIG. 14, the second layer 211a2 of the upper layer portion 211a is provided at a position in the finger electrode 211, that is farthest from semiconductor elements 31 and 32 and a semiconductor element 310. One end 410a of a tenth wire 410 is connected to the second layer 211a2. In an example shown in FIG. 14, a conductive layer 510 is provided on the second layer 211a2. The conductive layer 510 may contain, for example, gold. The one end 410a of the tenth wire 410 is connected to a connection point on the conductive layer 510. The semiconductor element 310 is placed on the second semiconductor element 32. The semiconductor element 310 may be bonded onto the second semiconductor element 32, for example, via an adhesive layer (not shown) such as NCP or a DAF. An opposite end 410b of the tenth wire 410 is connected to a pad (not shown) provided on the upper surface of the semiconductor element 310. In the example shown in FIG. 14, the tenth wire 410 connects the finger electrode 211 and the semiconductor element 310 by reverse bonding in which the finger electrode 211 side is subjected to first bonding and the pad side of the semiconductor element 310 is subjected to second bonding.

According to the example shown in FIG. 14, by increasing the number of steps of the finger electrode 211, even when three or more wires (e.g., wires 41, 42, and 410) are connected to the finger electrode 211, the clearance among the wires 41, 42, and 410 can be secured, and it is possible to prevent the contact between the capillary 100 and the wires 41 and 42.

### Sixth Modification

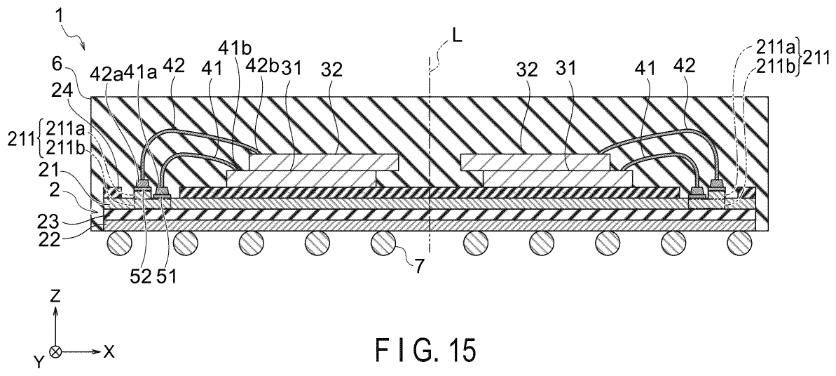

Next, a sixth modification of the first embodiment, in which the number of semiconductor elements to be mounted is increased in a surface direction of the wiring board 2, will be described while focusing on the differences from the first embodiment. FIG. 15 is a sectional view showing the semiconductor device 1 according to the sixth modification of the first embodiment. With reference to FIG. 12, an example has been described in which the number of semiconductor elements to be mounted is increased in a surface normal direction (Z-direction) of the wiring board, that is, in the thickness direction. In contrast, as shown in FIG. 15, the number of semiconductor elements 31 and 32 to be mounted may be increased in the surface direction (X-direction) of the wiring board 2. The semiconductor device 1 shown in FIG. 15 roughly corresponds to a configuration in which the semiconductor device 1 shown in FIG. 1 and a semiconductor device obtained by inverting the semiconductor device 1 shown in FIG. 1 about the Z-axis, are combined with each other at an imaginary line L in FIG. 15. However, the detailed configurations of the wiring layers 21 and 22 are adapted to the configuration in FIG. 15. In the example shown in FIG. 15, it is possible to ensure the clearance between the wires 41 and 42 while increasing the number of semiconductor elements to be mounted, as in the case of FIG. 12.

### Seventh Modification

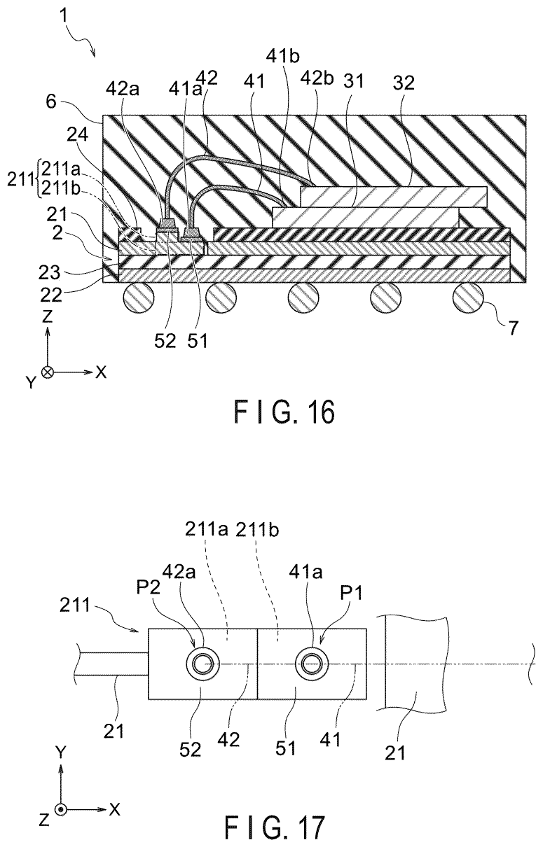

Next, a modification of the wiring layer 21 will be described while focusing on the differences from the first embodiment. FIG. 16 is a sectional view showing the semiconductor device 1 according to a seventh modification of the first embodiment. FIG. 17 is a plan view showing a finger electrode 211 in the semiconductor device 1 according to the seventh modification of the first embodiment.

The example has been described with reference to FIGS. 1 and 2, in which both the end portions of the finger electrode 211 in an extension direction (X-direction) are connected to the uppermost wiring layer 21. In contrast, as shown in FIGS. 16 and 17, one end of the finger electrode 211 in the extension direction (an end portion in the X-direction in FIGS. 16 and 17) may be spaced apart from the wiring layer 21. According to the example shown in FIGS. 16 and 17, it is possible to improve the degree of freedom in the arrangement of the finger electrode 211 and the wiring layer 21.

### Second Embodiment

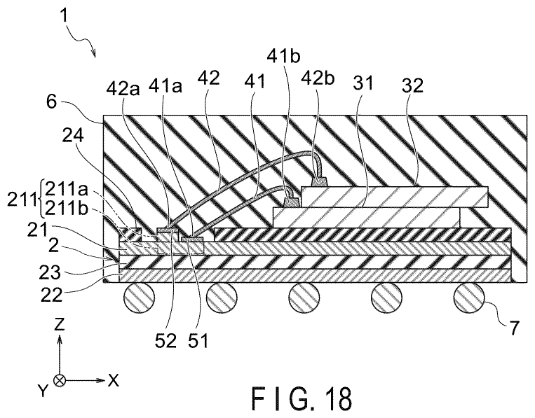

Next, a second embodiment in which the finger electrode 211 and the semiconductor elements 31 and 32 are connected to each other by positive bonding, will be described while focusing on the differences from the first embodiment. FIG. 18 is a sectional view showing the semiconductor device 1 according to the second embodiment. Up to this point, the example has been described of the semiconductor device 1 in which the finger electrode 211 and the semiconductor elements 31 and 32 are connected to each other by reverse bonding using the wires 41 and 42. In contrast, in an example shown in FIG. 18, the finger electrode 211 and the semiconductor elements 31 and 32 are connected to each other by positive bonding using wires 41 and 42.

In the second embodiment, the electrical connection between the finger electrode 211 and the semiconductor elements 31 and 32 includes a first step of connecting the opposite end 41b of the first wire 41 to the first semiconductor element 31, and a second step after the first step, of connecting the one end 41a of the first wire 41 to the first connection point P1 (see FIG. 2) on the lower layer portion 211b. The electrical connection between the finger electrode 211 and the semiconductor elements 31 and 32 further includes a third step of connecting the opposite end 42b of the second wire 42 to the second semiconductor element 32, and a fourth step after the third step, of connecting the one end 42a of the second wire 42 to the second connection point P2 on the upper layer portion 211a.

More specifically, in the second embodiment, first bonding for connecting the opposite end 41b of the first wire 41 to a pad (not shown) of the first semiconductor element 31, is first performed by using the capillary 100. Thereafter, second bonding is performed for connecting the one end 41a of the first wire 41 onto the lower layer portion 211b. As a result, the finger electrode 211 and the first semiconductor element 31 are connected to each other by positive bonding.

Next, first bonding is performed for connecting the opposite end 42b of the second wire 42 to a pad (not shown) of the second semiconductor element 32. Next, second bonding is performed for connecting the one end 42a of the second wire 42 onto the upper layer portion 211a. As a result, the finger electrode 211 and the second semiconductor element 32 are connected to each other by positive bonding.

The arrangement of the upper layer portion 211a and the number of semiconductor elements described in the first embodiment may be applied to the second embodiment.

According to the second embodiment, the finger electrode 211 has the upper layer portion 211a, so that the clearance between the wires 41 and 42 can be secured as in the first embodiment. Furthermore, even when the second wire 42 sags, a short circuit is unlikely to occur.

While certain embodiments have been described, these embodiments have been presented by way of example only, and are not intended to limit the scope of the invention. Indeed, the novel devices and methods described herein may be embodied in a variety of other forms; furthermore, various omissions, substitutions and changes in the form of the embodiments described herein may be made without departing from the spirit of the invention. The accompanying claims and their equivalents are intended to cover such forms or modification as would fall within the scope and spirit of the invention.

What is claimed is:

1. A semiconductor device comprising:
a wiring board provided with a first electrode including a first portion and a second portion, wherein the first electrode includes a step between the second portion and the first portion, and the second portion is higher than the first portion with respect to a base layer of the wiring board;
a first semiconductor element located on the wiring board;
a second semiconductor element located on the first semiconductor element;
a first wire that has one end connected to a first connection point on the first portion and that has an opposite end connected to the first semiconductor element; and
a second wire that has one end connected to a second connection point on the second portion and that has an opposite end connected to the second semiconductor element.

2. The semiconductor device of claim 1, wherein the second portion is provided at a position that is farther away from the first semiconductor element and the second semiconductor element than the first connection point.

3. The semiconductor device of claim 1, wherein the opposite end of the first wire is closer to the first connection point than the opposite end of the second wire is to the first connection point.

4. The semiconductor device of claim 1, wherein a width of the second portion equals half of a width of the first portion in a direction connecting the first connection point and the second connection point.

5. The semiconductor device of claim 1, wherein the second portion is formed of the same material as a wiring of the wiring board.

6. The semiconductor device of claim 1, wherein the first wire and the second wire have the same electric potential.

7. The semiconductor device of claim 6, wherein the first wire and the second wire are power supply lines.

8. The semiconductor device of claim 6, wherein the first wire and the second wire are ground lines.

9. The semiconductor device of claim 1, wherein the second portion is placed directly on the first portion.

10. The semiconductor device of claim 1, wherein
the wiring board further includes a second electrode having a third portion and a fourth portion, the second electrode including a step between the fourth portion and the third portion, and the fourth portion being higher than the third portion with respect to the base layer,
the semiconductor device further includes a third wire that has one end connected to a third connection point on the fourth portion and that has an opposite end connected to the first semiconductor element or to the second semiconductor element, and
the fourth portion is placed on a first end of the third portion, the first end being closer to the first semiconductor element and the second semiconductor element than a second end of the third portion that is opposite to the first end.

11. The semiconductor device of claim 10, wherein the third wire is a signal line.

12. The semiconductor device of claim 1, wherein
the wiring board further includes a third electrode having a fifth portion and a sixth portion, the third electrode including a step between the sixth portion and the fifth portion, and the sixth portion being higher than the fifth portion with respect to the base layer, and
the semiconductor device further comprises:
a third semiconductor element located between the first semiconductor element and the second semiconductor element;
a fourth semiconductor element located on the second semiconductor element;
a fourth wire that has one end connected to a fourth connection point on the fifth portion and that has an opposite end connected to the third semiconductor element; and
a fifth wire that has one end connected to a fifth connection point on the sixth portion and that has an opposite end connected to the fourth semiconductor element.

13. A method for manufacturing a semiconductor device comprising:
forming a wiring board with an electrode including a first portion and a second portion, wherein the electrode has a step between the second portion and the first portion, and the second portion is higher than the first portion with respect to a base layer of the wiring board;
placing a first semiconductor element on the wiring board;
placing a second semiconductor element on the first semiconductor element;
connecting one end of a first wire to a first connection point on the first portion and connecting an opposite end of the first wire to the first semiconductor element; and
connecting one end of a second wire to a second connection point on the second portion and connecting an opposite end of the second wire to the second semiconductor element.

14. The method for manufacturing a semiconductor device of claim 13, further comprising:
between the forming of the wiring board and the placing of the first semiconductor element on the wiring board: forming an insulating film on the wiring board and processing the insulating film such that the electrode is exposed to outside the insulating film, wherein the first semiconductor element is placed on the processed insulating film.

15. The method for manufacturing a semiconductor device of claim 13, wherein
the connecting of the one end of the first wire to the first connection point on the first portion is performed after the connecting of the opposite end of the first wire to the first semiconductor element, and
the connecting of the one end of the second wire to the second connection point on the second portion is performed after the connecting of the opposite end of the second wire to the second semiconductor element.

16. The method for manufacturing a semiconductor device of claim 13, wherein
the connecting of the one end of the first wire to the first connection point on the first portion is performed before the connecting of the opposite end of the first wire to the first semiconductor element, and
the connecting of the one end of the second wire to the second connection point on the second portion is performed before the connecting of the opposite end of the second wire to the second semiconductor element.

17. The method for manufacturing a semiconductor device of claim 13, wherein the second portion is provided at a position that is farther away from the first semiconductor element and the second semiconductor element than the first connection point.

18. The method for manufacturing a semiconductor device of claim 13, wherein based on the connecting of the opposite end of the first wire and the opposite end of the second wire, the opposite end of the first wire is closer to the first connection point than the opposite end of the second wire is to the first connection point.

19. The method for manufacturing a semiconductor device of claim 13, wherein a width of the second portion equals half of a width of the first portion in a direction connecting the first connection point and the second connection point.

20. The method for manufacturing a semiconductor device of claim 13, wherein the second portion is formed of the same material as a wiring of the wiring board.
